(19) United States
(12) Patent Application Publication
(10) Pub. No.: US 2020/0243372 A1
(43) Pub. Date: Jul. 30, 2020

(54) SUSCEPTOR, SUBSTRATE PROCESSING APPARATUS AND PROTECTION METHOD

(71) Applicant: Tokyo Electron Limited, Tokyo (JP)

(72) Inventor: Tadashi Aoto, Kurokawa-gun (JP)

(21) Appl. No.: 16/748,966

(22) Filed: Jan. 22, 2020

(30) Foreign Application Priority Data
Jan. 24, 2019 (JP) 2019-009872

(51) Int. Cl. H01L 21/687; H01L 21/3065; H01J 37/32; H01L 21/683; H01L 21/67

(52) U.S. Cl. CPC H01L 21/68714; H01L 21/3065; H01L 21/67098; H01J 37/32807; H01L 21/6831; H01J 37/32715

(57) ABSTRACT

A susceptor includes a base; a substrate placing member provided on the base; a bonding layer configured to bond the base and the substrate placing member; and a protection member disposed in a space which an outer peripheral surface of the bonding layer faces and allowed to deactivate a radical while having gas permeability.

### CROSS-REFERENCE TO RELATED APPLICATION

This application claims the benefit of Japanese Patent Application No. 2019-009872 filed on Jan. 24, 2019, the entire disclosure of which is incorporated herein by reference.

### TECHNICAL FIELD

The various aspects and embodiments described herein pertain generally to a susceptor, a substrate processing apparatus and a protection method.

### BACKGROUND

Conventionally, there is known a substrate processing apparatus configured to perform a plasma processing on a substrate such as a semiconductor wafer. Such a substrate processing apparatus has, between a base and a substrate placing member, a bonding layer which bonds the base and the substrate placing member. The bonding layer is consumed by plasma, starting from an outer peripheral surface thereof. If the bonding layer is consumed and the outer peripheral surface thereof is thus diminished, a space is generated, and a temperature control in a portion where the space is generated becomes non-uniform, resulting in deterioration of uniformity of etching characteristics. As a resolution, to block introduction of the plasma and protect the bonding layer in this substrate processing apparatus, an O-ring is disposed in a gap, between the base and the substrate placing member, which the outer peripheral surface of the bonding layer faces (see, for example, Patent Document 1).

Patent Document 1: Japanese Patent Laid-open Publication No. 2014-053481

### SUMMARY

In one exemplary embodiment, a susceptor includes a base; a substrate placing member provided on the base; a bonding layer configured to bond the base and the substrate placing member; and a protection member disposed in a space which an outer peripheral surface of the bonding layer faces and allowed to deactivate a radical while having gas permeability.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view illustrating a configuration of a plasma processing apparatus according to an exemplary embodiment;

FIG. 2 is a schematic cross sectional view illustrating an example configuration of major components of a susceptor in the plasma processing apparatus of FIG. 1;

FIG. 3 is a diagram illustrating an example structure of a protection member made of a mesh material;

FIG. 4 is a diagram illustrating an example where the protection member is disposed in a gap between a base and an electrostatic chuck; and

FIG. 5 is a diagram illustrating another example where the protection member is disposed in the gap between the base and the electrostatic chuck.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described in detail with reference to the accompanying drawings. In the various drawings, same or corresponding parts will be assigned same reference numerals.

Conventionally, there is known a substrate processing apparatus configured to perform a substrate processing such as a plasma processing on a substrate such as a semiconductor wafer. Such a substrate processing apparatus has, between a base and a substrate placing member, a bonding layer which bonds the base and the substrate placing member. The bonding layer is consumed by plasma, starting from an outer peripheral surface thereof. In the substrate processing apparatus, if the bonding layer is consumed and the outer peripheral surface thereof is thus diminished, a space is generated, and a temperature control in a portion where the space is generated becomes non-uniform, resulting in deterioration of in-surface uniformity of etching characteristics. As a resolution, to block introduction of the plasma and protect the bonding layer in this substrate processing apparatus, an O-ring is disposed in a gap, between the base and the substrate placing member, which the outer peripheral surface of the bonding layer faces (see, for example, Patent Document 1).

However, the O-ring may be protruded from this gap, between the base and the substrate placing member, which the outer peripheral surface of the bonding layer faces, as the O-ring is sucked when evacuation is performed. Further, the O-ring may be protruded from the gap, between the base and the substrate placing member, which the outer peripheral surface of the bonding layer faces, as a load caused by thermal expansion or thermal contraction of the base and the substrate placing member is applied to the O-ring. Furthermore, the O-ring may be protruded from the gap, between the base and the substrate placing member, which the outer peripheral surface of the bonding layer faces due to thermal expansion of the O-ring itself. If the O-ring is protruded, the plasma may enter the gap to reach the outer peripheral surface of the bonding layer. As a result, the bonding layer may be consumed by the plasma.

[Configuration of Plasma Processing Apparatus]

First, the substrate processing apparatus will be explained. The substrate processing apparatus is configured to perform a plasma processing on a substrate. An exemplary embodiment will be described for a case where the substrate processing apparatus is a plasma processing apparatus configured to perform a plasma etching on a semiconductor wafer (hereinafter, simply referred to as “wafer”) as the substrate.

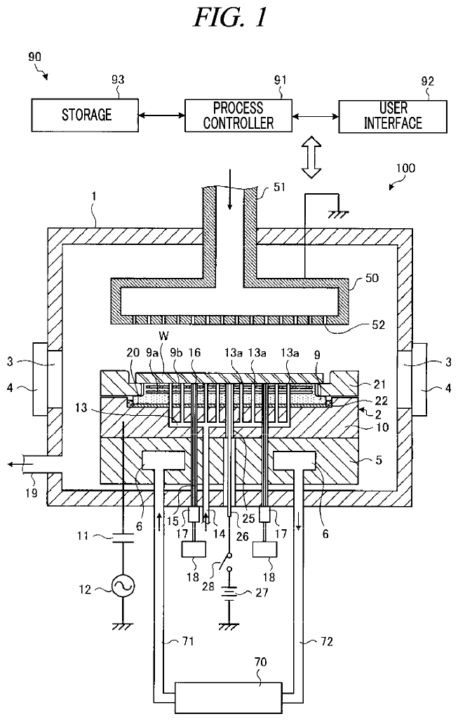

FIG. 1 is a schematic cross sectional view illustrating a configuration of a plasma processing apparatus 100 according to the exemplary embodiment. As depicted in FIG. 1, the plasma processing apparatus 100 has a processing chamber 1 which is hermetically sealed and electrically grounded. The processing chamber 1 is of a cylindrical shape and is made of, for example, aluminum. The processing chamber 1 confines a processing space in which plasma is formed. The processing chamber 1 is provided with an opening 3 through which the wafer W is carried into or out of the processing chamber 1; and a gate valve 4 configured to be opened or closed via a hermetically sealing sealant. The sealant may be, but not limited to, an O-ring.

Though not shown in FIG. 1, a load lock chamber is connected to the processing chamber 1 via the gate valve 4, and a transfer device is provided in the load lock chamber. The transfer device is configured to carry the wafer W into or out of the processing chamber 1.

An exhaust opening 19 for decompressing the processing chamber 1 is formed in a lower portion of a sidewall of the processing chamber 1. The exhaust opening 19 is connected to a non-illustrated vacuum exhaust device via an opening/closing valve such as, but not limited to, a butterfly valve. The vacuum exhaust device may be, for example, a rotary pump or a turbo molecular pump.

Further, a susceptor 2 configured to support the wafer W thereon is provided within the processing chamber 1. The susceptor 2 includes a base 10 and an electrostatic chuck (ESC) 9.

The base 10 has a substantially columnar shape and is made of a conductive metal such as, but not limited to, aluminum. The base 10 serves as a lower electrode. The base 10 is supported by a base supporting table 5. The base supporting table 5 has a substantially columnar shape and is made of a conductive metal such as, but not limited to, aluminum. The base supporting table 5 has therein a cooling jacket 6 which stores a cooling medium therein. The cooling jacket 6 is provided with a path 71 through which the cooling medium is introduced into the cooling jacket 6; and a path 72 through which the cooling medium is discharged from the cooling jacket 6. The path 71 and the path 72 are hermetically formed through a bottom surface of the processing chamber 1. A coolant having a preset temperature is supplied into the cooling jacket 6 to be circulated therein via the paths 71 and 72 from a chiller 70. Accordingly, the base supporting table 5 and the base 10 are controlled to a preset temperature.

The following description will be provided for a case where the cooling jacket 6 is provided within the base supporting table 5. However, the exemplary embodiment is not limited thereto. By way of example, the cooling jacket 6 may be provided within the base 10.

The base 10 is connected to a high frequency power supply 12 via a matching device 11. The high frequency power supply 12 is for plasma formation and is configured to supply a high frequency power having a preset frequency (e.g., 13.56 MHz or 40 MHZ) to the base 10 of the susceptor 2.

The electrostatic chuck 9 is made of, by way of example, ceramic (having a linear thermal expansion coefficient of about 7.1×10⁻⁶ (cm/cm/° C.)). The electrostatic chuck 9 has therein an electrode plate 9b and a heater 9a. A top surface of the electrostatic chuck 9 is of a flat disk shape, and this top surface is configured as a placing surface on which the wafer W is placed. The electrode plate 9b is connected to one end of a conductive line 25, and the other end of the conductive line 25 is connected to a power feed rod 26. The conductive line 25 is enclosed by an insulating member such as Teflon (registered trademark) embedded in the base 10. The power feed rod 26 is made of, but not limited to, copper and is configured to supply a high voltage ranging from about 200 V to about 3 KV. The power feed rod 26 penetrates the bottom surface of the processing chamber 1 hermetically while being insulated from the processing chamber 1, and is connected to a DC power supply 27 via an electronic switch 28. The electronic switch 28 is turned ON or OFF in response to a non-illustrated control signal that controls the apparatus. As a DC voltage is applied to the electrode plate 9b from the DC power supply 27, the wafer W is attracted to the electrode plate 9b by a Coulomb force. The electrostatic chuck 9 is an example of a substrate placing member.

Further, an edge ring 21 is disposed on a peripheral portion of the electrostatic chuck 9 to surround the wafer W placed on the placing surface of the electrostatic chuck 9. The edge ring 21 is made of, by way of example, quartz. Further, the edge ring 21 is also called a focus ring.

The base 10 and the electrostatic chuck 9 are bonded by a bonding layer 20. A protection member 22 is disposed in a space which an outer peripheral surface of the bonding layer 20 faces. The protection member 22 is a member configured to protect the bonding layer 20 from the plasma. Structures of the bonding layer 20 and the protection member 22 will be elaborated later.

Further, through holes 16 are formed through the base 10, the base supporting table 5, the bonding layer 20 and the electrostatic chuck 9. A pusher pin 15 which is electrically grounded via a resistor or an inductance is provided in each through hole 16. The pusher pin 15 is connected to an air cylinder 18 as a vertical moving mechanism via an expansible/contractible bellows 17 which seals the processing chamber 1 hermetically. The pusher pin 15 is moved up and down by the air cylinder 18 when the wafer W is transferred from/to the transfer device of the load lock chamber, and when the wafer W is brought into contact with or separated from the electrostatic chuck 9.

A multiple number of through holes 13a for uniformly supplying a heat transfer medium to a rear surface of the wafer W is formed through the base 10 and the electrostatic chuck 9. The through holes 13a are connected to a gas storage room 13 which allows a pressure of a He gas applied to the through holes 13a to be uniform. The gas storage room 13 is connected to a supply line 14 through which the heat transfer medium is introduced into the processing chamber 1 from the outside. The heat transfer medium may be, but not limited to, a He gas as an inert gas. However, the heat transfer medium may not be limited thereto, and any of various kinds of gases may be used.

An upper electrode 50 is disposed above the base 10. The upper electrode 50 is electrically grounded. A processing gas is supplied into the upper electrode 50 through a gas supply line 51. This processing gas is discharged toward the wafer W through a multiple number of small holes 52 radially arranged in a bottom wall of the upper electrode 50. Here, as the high frequency power supply 12 is turned ON, plasma of the discharged processing gas is formed between the upper electrode 50 and the wafer W.

An overall operation of the plasma processing apparatus 100 having the above-described configuration is controlled by a controller 90. The controller 90 includes a process controller 91 having a CPU and configured to control individual components of the plasma processing apparatus 100; a user interface 92; and a storage 93.

The user interface 92 includes a keyboard through which a process manager inputs commands to manage the plasma processing apparatus 100, a display which visually displays an operational status of the plasma processing apparatus 100, and so forth.

The storage 93 stores therein a control program (software) for implementing various processings performed in the plasma processing apparatus 100 under the control of the process controller 91 or a recipe including processing condition data, etc. In response to an instruction from the user interface 92 or the like, a necessary recipe is retrieved from the storage 93 and executed by the process controller 91, so that a required processing is performed in the plasma processing apparatus 100 under the control of the process controller 91. The control program or the recipe including the processing condition data, etc. may be used while being stored on a computer-readable recording medium (e.g., a hard disk, a CD, a flexible disk or a semiconductor memory), or may be used on-line by being transmitted through, e.g., a dedicated line, whenever necessary.

[Configuration of Major Components of Susceptor]

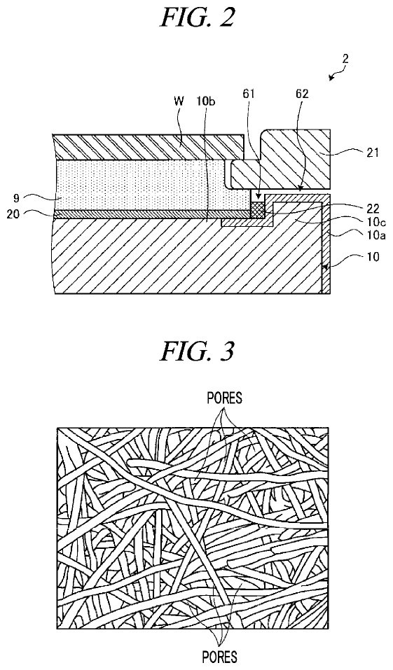

Now, referring to FIG. 2, a configuration of major components of the susceptor 2 will be described. FIG. 2 is a schematic cross sectional view illustrating an example configuration of the major components of the susceptor 2 in the plasma processing apparatus 100 of FIG. 1. As depicted in FIG. 2, the susceptor 2 includes the base 10 and the electrostatic chuck 9 disposed on the base 10.

The base 10 is of a substantially columnar shape and has a thermally sprayed film 10a on a front surface thereof. The thermally sprayed film 10a covers the front surface of the base 10 such that the front surface of the base 10 is not exposed to the inside of the processing chamber 1. The thermally sprayed film 10a is made of, by way of non-limiting example, Al₂O₂ or Y₂O₃. The base 10 has a protruding portion 10c at a peripheral portion thereof, and a height of this protruding portion 10c is higher than that of a central portion 10b of the base 10.

The electrostatic chuck 9 is disposed on the central portion 10b of the base 10. The electrostatic chuck 9 has the disk shape having the flat top surface, and this top surface is configured as the placing surface on which the wafer W is placed. Further, a gap 61 extending in a longitudinal direction is provided between an outer peripheral surface of the electrostatic chuck 9 and an inner peripheral surface of the protruding portion 10c of the base 10.

The edge ring 21 is disposed at the peripheral portion of the electrostatic chuck 9 to surround the wafer W placed on the placing surface of the electrostatic chuck 9. The edge ring 21 is disposed at the peripheral portion of the electrostatic chuck 9 such that a bottom surface of the edge ring 21 is spaced apart from a top surface of the protruding portion 10c of the base 10. That is, a gap 62, which extends in a transversal direction and is connected to the gap 61, is formed between the bottom surface of the edge ring 21 and the top surface of the protruding portion 10c of the base 10. Accordingly, since a labyrinth path ranging from the gap 62 to the gap 61 is built, the plasma is suppressed from reaching the gap 61.

The base 10 and the electrostatic chuck 9 are bonded by the bonding layer 20. The bonding layer 20 bonds the electrostatic chuck 9 and the base 10 and allows a heat transfer between the electrostatic chuck 9 and the base 10. The outer peripheral surface of the bonding layer 20 faces the gap 61 between the inner peripheral surface of the protruding portion 10c of the base 10 and the outer peripheral surface of the electrostatic chuck 9.

The protection member 22 is disposed in the space which the outer peripheral surface of the bonding layer 20 faces, that is, in the gap 61 between the inner peripheral surface of the protruding portion 10c of the base 10 and the outer peripheral surface of the electrostatic chuck 9. The protection member 22 is formed of a member capable of deactivating radicals and having gas permeability.

In the plasma processing apparatus 100, however, when the plasma etching is performed, the radicals in the plasma may go around the edge ring 21 to enter the gap 61. As a result, the bonding layer 20 is consumed, starting from the outer peripheral surface thereof. In the plasma processing apparatus 100, if the bonding layer 20 is consumed and the outer peripheral surface thereof is thus diminished, a space is formed at a portion of the outer peripheral surface of the bonding layer 20. In the plasma processing apparatus 100, a temperature control of the electrostatic chuck 9 at the portion where the space is formed becomes non-uniform, so that in-surface uniformity of etching characteristics is deteriorated.

For this reason, conventionally, maintenance is performed regularly in the plasma processing apparatus 100. For example, in the plasma processing apparatus 100, as the bonding layer 20 is consumed, there is performed maintenance of re-forming the bonding layer 20 by replacing the electrostatic chuck 9. In the plasma processing apparatus 100, however, if the maintenance is required in a short period of time, the work of the maintenance is increased, resulting in an increase of maintenance cost of the plasma processing apparatus 100. Furthermore, in the plasma processing apparatus 100, if the maintenance is required in the short period of time, a downtime during which the plasma processing cannot be performed is increased, resulting in deterioration of productivity.

In view of this, in the plasma processing apparatus 100, the protection member 22 capable of deactivating the radicals and having the gas permeability is disposed in the gap 61, as depicted in FIG. 2. The protection member 22 may be made of a porous body having a multiple number of pores distributed in an irregular manner. The protection member 22 may be formed of a fabric material such as a mesh, a non-woven fabric, twisted threads or a woven fabric, or a sponge or the like, or formed by combining the fabric material and the sponge.

In the plasma processing apparatus 100 according to the present exemplary embodiment, the protection member 22 made of a mesh material is disposed in the gap 61. The protection member 22 is formed by winding, for example, a fluorine-containing resin material in a mesh shape. The fluorine-containing resin material may be, by way of non-limiting example, Teflon (registered trademark).

FIG. 3 is a diagram illustrating an example structure of the protection member 22 made of the mesh material. As depicted in FIG. 3, the protection member 22 has a mesh-shaped structure in which a multiple number of pores are distributed in an irregular manner, and has a property allowing the radicals to collide with inner wall surfaces of the multiple number of pores to thereby deactivate the radicals.

In the plasma processing apparatus 100 according to the present exemplary embodiment, by disposing the protection member 22 made of the mesh material in the gap 61, the consumption of the bonding layer 20 can be suppressed. It is deemed to be because a density of the radicals around the outer peripheral surface of the bonding layer 20 is reduced as the mesh material deactivates the radicals so that a pace of the consumption is decreased.

The protection member 22 is disposed in the gap 61 in a compressed state. Accordingly, diameters of the multiple number of pores in the protection member 22 are reduced, so that the deactivation of the radicals is accelerated. Therefore, the consumption of the bonding layer 20 can be suppressed more efficiently.

[Assembly Sequence of Susceptor]

Now, an assembly sequence of the susceptor 2 according to the present exemplary embodiment will be explained. First, the base 10 and the electrostatic chuck 9 are bonded by the bonding layer 20. Then, the protection member 22 capable of deactivating the radicals and having the gas permeability is disposed in the space (for example, in the gap 61 shown in FIG. 2) which the outer peripheral surface of the bonding layer 20 faces. Then, the assembly of the susceptor 2 shown in FIG. 2 is completed. Here, the process of placing the protection member 22 in the space which the outer peripheral surface of the bonding layer 20 faces is an example of a protection method of protecting the bonding layer 20.

As stated above, since the plasma processing apparatus 100 according to the present exemplary embodiment has the labyrinth path, the protection member 22 is disposed in the gap 61 which is an end of the labyrinth structure or a vicinity thereof. Accordingly, the radicals passing through the labyrinth path can be deactivated efficiently. Here, however, even if the plasma processing apparatus 100 does not have the labyrinth path, the radicals can still be deactivated by disposing the protection member 22 in the space which the outer peripheral surface of the bonding layer 20 faces.

Further, in case that the protection member 22 does not have the gas permeability, like the O-ring, the protection member 22 may be protruded from the gap 61 if a gas existing between the protection member 22 and the bonding layer 20 is sucked in by the evacuation of the processing chamber 1. Thus, it is desirable that the protection member 22 has the gas permeability to allow the gas existing between the protection member 22 and to bonding layer 20 to pass therethrough. In this way, the problem in which the protection member 22 is protruded from the gap 61 is avoided, so that the plasma can be suppressed from entering the gap 61 and reaching the outer peripheral surface of the bonding layer 20.

In addition, it is desirable that the protection member 22 has elasticity so that it extends and contracts in a direction in which the thermal expansion or the thermal contraction of the base 10 and the electrostatic chuck 9 is absorbed. Accordingly, the problem, in which the protection member 22 is protruded from the gap 61 as the load of the thermal expansion or the thermal contraction of the base 10 and the electrostatic chuck 9 is applied to the protection member 22, can be avoided, so that the plasma can be suppressed from entering the gap 61 and reaching the outer peripheral surface of the bonding layer 20.

The plasma processing apparatus 100 according to the present exemplary embodiment as described above includes the base 10; the electrostatic chuck 9 which is disposed on the base 10 and on which the wafer W as the plasma processing target is placed; the bonding layer 20 configured to bond the electrostatic chuck 9 and the base 10; and the protection member 22. The protection member 22 is disposed in the gap 61, and is formed to be capable of deactivating the radicals while having the gas permeability. Accordingly, in the plasma processing apparatus 100, the consumption of the bonding layer 20 by the plasma can be suppressed. As a result, in the plasma processing apparatus 100, the work of the maintenance of the bonding layer 20 can be reduced, so that the maintenance cost of the plasma processing apparatus 100 can be reduced. Furthermore, in the plasma processing apparatus 100, the downtime during which the plasma processing cannot be performed is also reduced, so that the deterioration of the productivity can be suppressed.

Furthermore, it should be noted that the above-described exemplary embodiments are illustrative in all aspects and are not anyway limiting. The above-described exemplary embodiments may be omitted, replaced and modified in various ways without departing from the scope and the spirit of claims.

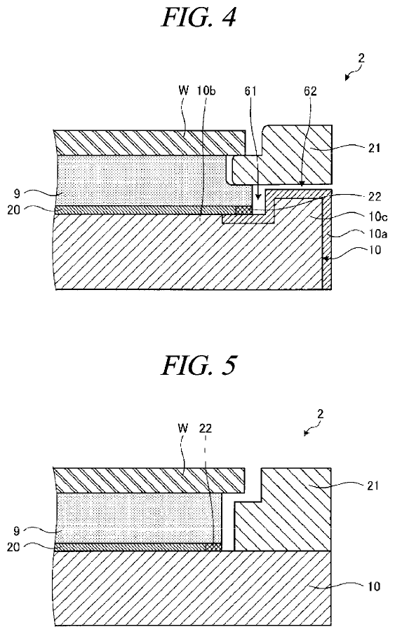

By way of example, if a gap which the bonding layer 20 faces exists between the central portion 10b of the base 10 and the electrostatic chuck 9, the protection member 22 may be disposed in this gap. FIG. 4 is a diagram illustrating an example where the protection member 22 is disposed in a gap between the base 10 and the electrostatic chuck 9. The outer peripheral surface of the bonding layer 20 shown in FIG. 4 is located at an inner position than the outer peripheral surface of the electrostatic chuck 9 in a radial direction. As a result, the gap which the bonding layer 20 faces is formed between the central portion 10b of the base 10 and the electrostatic chuck 9. The protection member 22 is disposed in this gap, between the central portion 10b of the base 10 and the electrostatic chuck 9, which the bonding layer 20 faces.

Further, even if the protruding portion 10c does not exist at the peripheral portion of the base 10, the protection member 22 can still be disposed in the gap, between the base 10 and the electrostatic chuck 9, which the bonding layer 20 faces. FIG. 5 is a diagram illustrating another example where the protection member 22 is disposed in the gap between the base 10 and the electrostatic chuck 9. The outer peripheral surface of the bonding layer 20 shown in FIG. 5 is located at an inner position than the outer peripheral surface of the electrostatic chuck 9 in the radial direction. Thus, the gap which the bonding layer 20 faces is formed between the base 10 and the electrostatic chuck 9. Further, the base 10 shown in FIG. 5 has a disk shape with the flat top surface, and the electrostatic chuck 9 is disposed on the central portion of the top surface of the base 10 and the edge ring 21 is disposed on the peripheral portion of the top surface of the base 10. That is, the base 10 does not have the protruding portion 10c (see FIG. 2 and FIG. 4) at the peripheral portion thereof. Even in this case, the protection member 22 is disposed in the gap, between the base 10 and the electrostatic chuck 9, which the bonding layer 20 faces.

According to the present disclosure, consumption of the bonding layer by plasma can be suppressed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A susceptor, comprising:
a base;
a substrate placing member provided on the base;
a bonding layer configured to bond the base and the substrate placing member; and
a protection member disposed in a space which an outer peripheral surface of the bonding layer faces and allowed to deactivate a radical while having gas permeability.

2. The susceptor of claim 1,
wherein the protection member is made of a porous body.

3. The susceptor of claim 1,
wherein the protection member is made of a fabric material or a sponge.

4. The susceptor of claim 1,
wherein the protection member is made of a mesh, an non-woven fabric, a twisted thread or a woven fabric.

5. The susceptor of claim 1,
wherein the protection member is made of a fluorine containing resin material.

6. The susceptor of claim 1,
wherein the protection member has elasticity in which the protection member extends and contracts in a direction in which thermal expansion or thermal contraction of the base and the substrate placing member is absorbed.

7. The susceptor of claim 1,
wherein the base has a protruding portion at an outside of the substrate placing member, and
the protection member is disposed in a compressed state in a gap formed by an inner peripheral surface of the protruding portion and an outer peripheral surface of the substrate placing member.

8. A substrate processing apparatus, comprising:
a processing chamber in which plasma is formed; and
the susceptor as claimed in claim 1, and disposed in the processing chamber.

9. A protection method of protecting a bonding layer in a susceptor including a base; a substrate placing member provided on the base; and the bonding layer configured to bond the base and the substrate placing member, the protection method comprising:
disposing a protection member, allowed to deactivate a radical while having gas permeability, in a space which an outer peripheral surface of the bonding layer faces.
